(19) United States
(12) Patent Application Publication
(10) Pub. No.: US 2006/0073619 A1
(43) Pub. Date: Apr. 6, 2006

(54) Semiconductor fabricating apparatus and method and apparatus for determining state of semiconductor fabricating process

(76) Inventors: Tatehito Usui, Chiyoda (JP); Motohiko Yoshigai, Hikari (JP); Tsuyoshi Yoshida, Hikari (JP); Hideyuki Yamamoto, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/293,213

(22) Filed: Dec. 5, 2005

Related U.S. Application Data
(63) Continuation of application No. 10/230,309, filed on Aug. 29, 2002.

(51) Int. Cl. H01L 21/00; H01L 21/306; C23F 1/00

(52) U.S. Cl. 438/9; 156/345.24

(57) ABSTRACT

In a semiconductor device fabrication apparatus for performing an etching process for a semiconductor wafer having a plurality of films formed on a surface thereof and disposed in a chamber, by using plasma generated in the chamber, a change in light of multi-wavelength from the surface of the semiconductor wafer is measured during a predetermined period of the etching process, and a state of the etching process is judged from the displayed change amount of light of multi-wavelength.

### CROSS-REFERENCE TO RELATED APPLICATION

The present invention is related to application Ser. No. 09/946,504 filed 6 Sep. 2001, allowed, and application Ser. No. 10/678,412 filed 2 Nov. 2004, pending, and application Ser. No. 11/126,159, filed 11 May 2005, pending, and is a continuation of application Ser. No. 10/230,309 filed 29 Aug. 2002, pending, the contents of all of which are incorporated herein by reference in their entirety.

### BACKGROUND OF THE INVENTION

The present invention relates to a semiconductor device fabricating apparatus having a means for measuring an etched depth.

In the manufacture of semiconductor devices, dry etching has been in wide use in etching layers of various materials such as dielectric material and insulating material formed on the surface of a semiconductor wafer, and in forming patterns in these layers. It is important in controlling dry etching to accurately determine an etching endpoint during the processing of each of these layers at which desired etching depth and film thickness are obtained.

During the dry etching of a semiconductor wafer, the intensity of light emission of a specific wavelength in a plasma beam changes as the etching of a particular film proceeds. One example method currently available for determining the state of etching such as an endpoint and film thickness of a semiconductor wafer etching process involves detecting a change in the intensity of light emission of a particular wavelength emitted from a plasma during the dry etching and, based on the result of detection, determining an etching process endpoint and a film thickness of a particular film. In order to improve a detection precision, it is necessary to reduce an erroneous detection to be caused by noise-induced variations in a detected waveform.

As techniques of detecting an endpoint of etching a semiconductor wafer, it is know to use an interferometer as disclosed in Japanese Patent Laid-open Publication No. 5-179467 (Prior Art 1), Japanese Patent Laid-open Publication No. 8-274082 (Prior Art 2), Japanese Patent Laid-open Publication No. 2000-97648 (Prior Art 3), Japanese Patent Laid-open Publication No. 2000-106356 and etc.

In Japanese Patent Laid-open Publication No. 5-179467 (Prior Art 1), an endpoint of etching is detected by detecting interference light (plasma light) by using color filters of red, green and blue. In Japanese Patent Laid-open Publication No. 8-274082 (U.S. Pat. No. 5,658,418) (Prior Art 2), extreme values of an interference waveform (maximum and minimum of a waveform: zero-cross points of a differential waveform) are counted by utilizing a change with time of an interference waveform between two wavelengths and its differential waveform. An etching rate is calculated by measuring a time taken for the count to reach a predetermined value, a remaining time taken to obtain a predetermined film thickness is calculated in accordance with the calculated etching rate, and the etching process is stopped in accordance with the calculated remaining etching time. In Japanese Patent Laid-open Publication No. 2000-97648 (Prior Art 3), a difference waveform (using a wavelength as a parameter) is obtained between a light intensity pattern (using a wavelength as a parameter) of interference light before the process and a light intensity pattern of interference light after or during the process. A step (film thickness) is calculated by comparing the difference waveform and a difference waveform stored in a database. In Japanese Patent Laid-open Publication No. 2000-106356, a thickness of a film coated by a rotary coater is determined by measuring a change with time of interference light beams of a plurality of wavelengths.

It is important to stop the etching by determining an etching endpoint so that the thickness of a remaining film is as near as or equal to a predetermined thickness. According to conventional techniques, a film thickness is monitored and an endpoint is adjusted on the assumption that the etching rate of each layer is constant. An etching rate to be used as a standard is obtained, for example, by processing a sample wafer. According to these techniques, an etching process is stopped when a time corresponding to a predetermined film thickness lapses.

An actual film, for example, an SiO₂ film formed by the LPCVD (low pressure chemical vapor deposition), however, is known to have a low reproductivity in terms of thickness (large variations in the thickness of films). An allowable error of thickness due to LPCVD process variations is, for example, equal to about 10% of an initial thickness of an SiO₂ film. Hence, the endpoint adjustment on the assumption of a constant etching rate according to the conventional technique cannot precisely measure the actual final thickness of an SiO₂ film left on a silicon substrate.

The above-described conventional techniques did not consider the following points:

(1) While an etching process is performed by using a mask (such as a resist film, a nitride film and an oxide film), interference light from the mask is superposed upon interference light from the mask. In order to detect the etching state of only a target film from interference light, it is necessary to eliminate the influence of interference light from the mask.

(2) During an etching process, not only a target film (such as a silicon film and an insulating film) but also a mask is etched. In this case, not only interference light from the target film but also interference light from the mask changes with time. In order to detect an etch amount (etch depth) of the target film by eliminating the influence of etching the mask, it is necessary to consider interference light from the mask. The conventional techniques did not consider this point.

(3) Initial thicknesses of a mask and a target film have a distribution in the whole area of a wafer manufactured by mass production processes, depending upon the device structure. Therefore, interference light from target layers of one type having different thicknesses is superposed. The conventional techniques did not consider sufficiently to eliminate such influence.

From these reasons, it is difficult to determine the state of an etching process, particularly a plasma etching process by accurately detecting an etch depth and a remaining film thickness of a target layer to be etched.

### SUMMARY OF THE INVENTION

It is an object of the present invention to provide a semiconductor device fabricating apparatus and a method of determining the state of a semiconductor device fabricating process, capable of solving the above-described problems associated with conventional techniques.

It is another object of the invention to provide a semiconductor device fabricating apparatus capable of fabricating a semiconductor device on a wafer at a high precision.

It is a further object of the invention to provide a method of determining the state of a semiconductor device fabricating process capable of highly precisely detecting an etch depth, a remaining film thickness and the like of a target film to be plasma etched.

The above objects of the invention can be achieved by a semiconductor device fabrication apparatus for performing an etching process for a semiconductor wafer having a plurality of films formed on a surface thereof and disposed in a chamber, by using plasma generated in the chamber, the apparatus comprising: a display unit for displaying a change in light of multi-wavelength, the light coming from the surface of the semiconductor wafer during a predetermined period of the etching process; and a unit of judging a state of the etching process in accordance with a displayed change amount of light of multi-wavelength.

The above objects of the invention can be achieved by a semiconductor device fabrication apparatus for performing an etching process for a semiconductor wafer having a plurality of films formed on a surface thereof and disposed in a chamber, by using plasma generated in the chamber, the apparatus comprising: a measuring unit for measuring light from a surface of the semiconductor wafer during a predetermined period during the etching process; a display unit for displaying data of a change in light measured by the measuring unit during the predetermined period; a calculation unit for calculating a state of the etching process by using the displayed data; and a controller for controlling the etching process in accordance with a calculation result of the calculation unit.

The above objects of the invention can be achieved by a semiconductor device fabricating apparatus comprising: a measuring instrument for detecting interference of light from a surface of a semiconductor wafer having a plurality of films formed on the surface thereof and being processed by generated plasma; a display unit for displaying a change in interference of the light during a predetermined period of the plasma process; and a judgement unit for judging a speed of the plasma process in accordance with a change with time of a wavelength of the light having a change in interference equal to or larger than a predetermined value or equal to or smaller than the predetermined value.

The above objects of the invention can be achieved by a method of judging a process state of a semiconductor device, comprising: a step of measuring interference of light from a surface of a semiconductor wafer having a plurality of films formed on the surface thereof and being processed by generated plasma; and a step of determining a thickness of one of the plurality of films of the semiconductor wafer in accordance with a change with time of a wavelength of the light having a change in the measured light interference equal to or larger than a predetermined value.

The above objects of the invention can be achieved by a method of judging a process state of a semiconductor device, comprising: a step of measuring a change in interference of light from a surface of a semiconductor wafer having a plurality of films formed on the surface thereof and being processed by generated plasma; and a step of superposing data of interference of light detected from a plurality of semiconductor wafers, and determining a thickness of one of the plurality of films of the semiconductor wafer in accordance with a change with time of a wavelength of the light having a change in light interference obtained from the superposed data equal to or larger than a predetermined value or equal to or smaller than the predetermined value.

Other objects, features and advantages of the invention will become apparent from the following description of the embodiments of the invention taken in conjunction with the accompanying drawings.

### BRIEF DESCRIPTION OF THE DRAWINGS

FIG. 1 is a schematic cross sectional view partially in blocks showing a semiconductor device fabricating apparatus according to a first embodiment of the invention.

FIG. 2 is a schematic cross sectional view illustrating light interference associated with a target film during an etching process according to the first embodiment.

FIG. 3 is a graph showing examples of data obtained by light interference according to the first embodiment.

FIG. 4 is a graph showing the etching state displayed on a display unit of the first embodiment by using the data shown in FIG. 2.

FIGS. 5A to 5E are graphs showing data of differential waveforms of interference light obtained during etching processes having different conditions.

FIGS. 6A to 6E are graphs showing patterns of differential waveforms of interference light shown in FIGS. 5A to 5E, the patterns being matched by using a specific parameter.

FIG. 7 is a flow chart illustrating a process of determining an etching state of the semiconductor device fabricating apparatus shown in FIG. 1.

FIG. 8 is a flow chart illustrating a process at Step 711 B shown in FIG. 7.

### DETAILED DESCRIPTION OF THE EMBODIMENTS

Embodiments of the invention will be described with reference to the accompanying drawings.

In each of the embodiments to follow, elements having the similar function to those of the first embodiment are represented by using identical reference numerals and the detailed description thereof is omitted. In the following embodiments, as a method of determining an endpoint of a semiconductor device fabricating process, a method of measuring an etch amount (etch depth and film thickness) during an etching process for a target film will be described. The invention is not limited only thereto, but it is applicable to a method of measuring a thickness and the like of a film to be formed by plasma CVD, sputtering or the like.

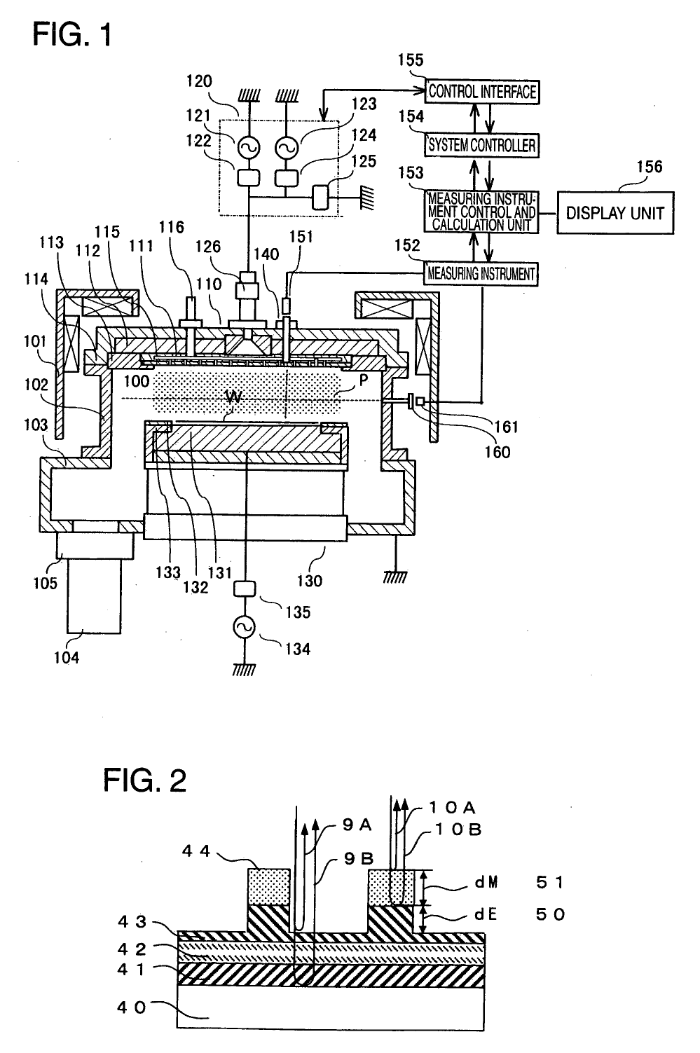

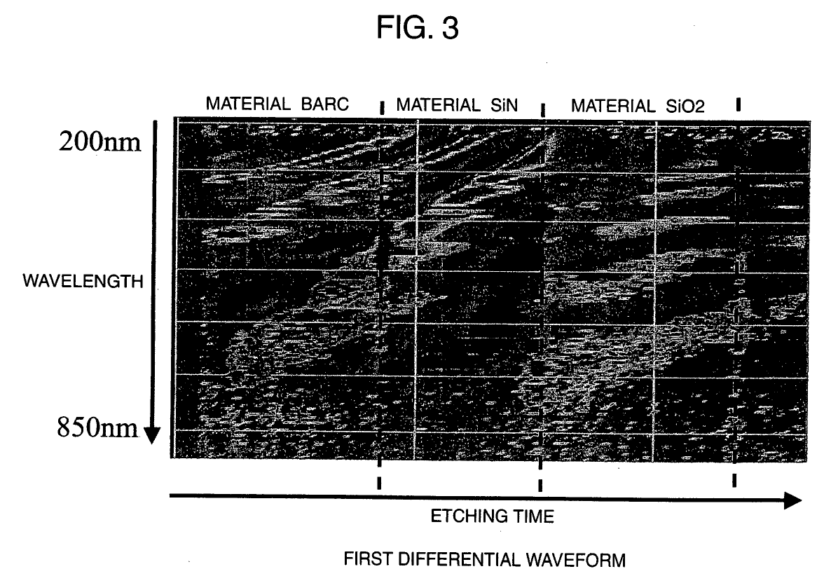

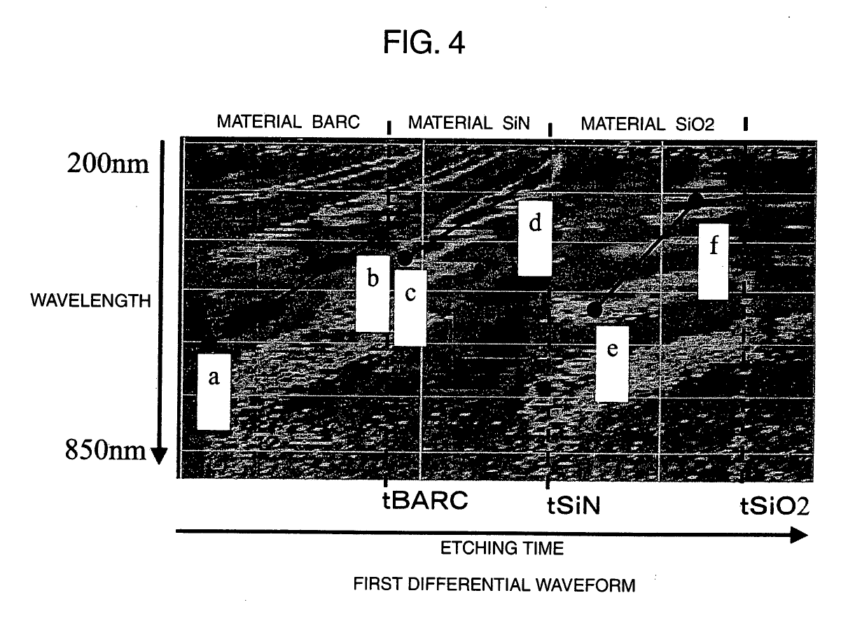

A first embodiment of the invention will be described with reference to FIGS. 1 to 4. FIG. 1 is a schematic cross sectional view partially in blocks showing a semiconductor device fabricating apparatus according to a first embodiment of the invention. FIG. 2 is a schematic cross sectional view illustrating light interference associated with a target film during an etching process according to the first embodiment. FIG. 3 is a graph showing examples of data obtained by light interference according to the first embodiment. FIG. 4 is a graph showing the etching state displayed on a display unit of the first embodiment by using the data shown in FIG. 2.

In this embodiment, for plasma etching of a member such as a semiconductor wafer, a standard pattern is set which represent a wavelength dependency of interference light data or its differential values relative to each etching amount of a sample member (sample wafer) and mask material of the sample member. Next, the intensities of interference light of multi-wavelength are measured for a sample member and a target member (target wafer), and actual patterns (using a wavelength as a parameter) are obtained which are representative of a wavelength dependency of data of the measured intensities of interference light or its differential data. The standard patterns of differential values are compared with actual patterns to determine an actual etching amount (process endpoint) of a member.

FIG. 1 is a schematic cross sectional view showing an embodiment in which the invention is applied to a plasma etching apparatus of the UHF band electromagnetic wave radiation and discharge under magnetic field type.

Referring to FIG. 1, a process chamber 100 is made of a vacuum container capable of reaching a vacuum degree of about 10⁻⁶ Torr. In the upper area of the process chamber 100, an antenna 110 as a plasma generator unit for radiating electromagnetic waves is disposed, and in the lower area of the process chamber 100, a lower electrode 130 on which a sample W such as a wafer is placed is disposed. The antenna 110 and lower electrode 130 are disposed facing each other in parallel. A magnetic field generating unit 101 made of, for example, an electromagnetic coil and a yoke, is disposed around the process chamber 100. The magnetic field generating unit 101 generates a magnetic field having a predetermined distribution and intensity. Interaction between an electromagnetic field generated by the antenna 110 and a magnetic field generated by the magnetic field generating unit 101 changes process gas introduced into the process chamber in a plasma state to thereby generate plasma P which processes the sample W on the lower electrode 130.

The inside of the process chamber 100 is evacuated to adjust the pressure by a vacuum exhaust system 104 and a pressure controller 105 connected to a vacuum chamber 103. The inner pressure can be set to a predetermined value, for example, in a range from 0.5 Pa or higher to 4 Pa or lower. The process chamber 100 and vacuum chamber 103 are set to the earth potential. A side wall 102 of the process chamber 100 is controlled to have a temperature of about 50° C. by an unrepresented temperature controller.

The antenna 110 for radiating electromagnetic waves is made of a disk conductor 111, a dielectric member 112 and a dielectric ring 113 and is supported by a housing 114 constituting part of the vacuum chamber. A plate 115 is mounted on the disk conductor 111 on the plasma side. Process gas for etching, film forming and the like for a sample is supplied from a gas supply port 116 at a predetermined flow rate and mixture ratio, made uniform in the disk conductor 111, and introduced into the process chamber 100 via a number of through holes formed through the plate 115. The temperature of the disk conductor 111 is controlled to be, for example, 30° C. by an unrepresented temperature controller. The antenna 110 is connected via an input terminal 126 to an antenna power source system 120 made of an antenna power source 121, an antenna bias power source 123, and matching circuit/filter systems 122, 124 and 125. It is preferable that the antenna power source 121 supplies a power of a UHF band frequency from 300 MHz to 900 MHz to make the antenna 110 radiate electromagnetic waves of the UHF band.

The antenna bias power source 123 applies a bias of a frequency range, for example, from about 100 kHz or several MHz to about 10 MHz to the plate 115 via the disk conductor 111 to control reaction on the surface of the plate 115. In etching an oxide film by using gas, particularly CF-based gas, the plate 115 is made of high purity silicon, carbon or the like so that reaction of F radicals and CFₓ radicals on the surface of the plate 115 can be controlled and the composition ratio of radicals can be adjusted. In this embodiment, the plate 115 is made of high purity silicon. The disk conductor 111 and housing are made of aluminum, and the dielectric member 112 and dielectric ring 113 are made of quartz. A distance (hereinafter called a gap) between the bottom surface of the plate 115 and the wafer W is set to 30 mm or longer and 150 mm or shorter, or more preferably to 50 mm or longer and 120 mm or shorter. In this embodiment, the antenna power source 121 has a frequency of 450 MHz, the antenna bias power source 122 has a frequency of 13.56 Mhz, and the gap is set to 70 mm.

In the lower area of the process chamber 100, the lower electrode 130 facing the antenna 110 is disposed. The sample W such as a wafer is placed on and adhered to the upper surface or sample holding surface of the lower electrode 130 by an electrostatic chucking unit 131. A sample holding ring 132 made of high purity silicon is disposed on an insulator 133 and around the outer periphery of the sample W. A bias power source 134 for supplying a bias power of preferably in a range from 400 kHz to 13.56 MHz is connected via a matching circuit/filter system 135 to the lower electrode 130 to control the bias to be supplied to the sample W. In this embodiment, the bias power source 134 has a frequency of 800 kHz.

Next, a measurement port 140 will be described which is provided in order to measure the surface state of the sample W. In this embodiment, the measurement port 140 is mounted on the antenna 110 facing the sample W, and can measure along the vertical direction the state of a thin film or the like on the surface of the sample W via a number of though holes formed through the plate 115, as will be later described. Another measurement port 140 is mounted at a measurement position corresponding to the outer periphery of the sample W or at an intermediate position between the outer periphery and center of the sample W so that information of the in-plane distribution on the surface of the sample W can be obtained. The positions of the measurement port are not limited only to two positions, outer periphery and intermediate positions. Only one position or three or more positions may also be used, or another layout may also be used.

Each of the measurement ports 140 is provided with an optical transmission unit 151 such as an optical fiber and a lens. The optical transmission unit 151 transmits optical information to a measuring instrument 152 made of, for example, a camera, an interference thin film meter, an image processing apparatus or the like. The optical information reflects the surface state of the wafer W, such as direct light from plasma P, reflection light or interference light of plasma P from the wafer W surface. The measuring instrument 152 is controlled by a measuring instrument control and calculation unit 153, and connected to an upper level system controller 154. The system controller 154 monitors and controls the state of the system or apparatus via a control interface 155. The calculation unit 153 may be an electronic circuit constituted of a plurality of memory chips and a microprocessor or an electronic circuit constituted of one chip such as a one-chip microcomputer.

The plasma etching apparatus of the embodiment is constructed as described above. By using this plasma etching apparatus, a process of etching a film, for example, a silicon oxide film is performed in the following manner.

First, after a wafer W to be processed is transported to the process chamber 100 by an unrepresented sample transport mechanism, it is placed on and chucked to the lower electrode 130, and if necessary, the height of the lower electrode is adjusted to set a predetermined gap. The inside of the process chamber 100 is evacuated by the vacuum exhaust system 106. Gas necessary for etching the sample W, e.g., C₄F₈, Ar and O₂ are supplied from the gas supply unit 116 to the process chamber 100 via the plate 115 of the antenna, at a predetermined flow rate and a predetermined mixture ratio, for example, Ar 400 sccm, C₄F₈ 15 sccm and O₂ 5 sccm. At the same time, the inside of the process chamber 100 is set to a predetermined pressure, e.g., 2 Pa. The magnetic field generating unit 101 generates generally a horizontal magnetic field under the plate 115, the magnetic field having approximately 160 Gausses corresponding to the intensity of an electron cyclotron resonance magnetic field of a frequency of 450 MHz of the antenna power source 121. The antenna power source 121 makes the antenna 110 radiate electromagnetic waves in the UHF band so that plasm P is generated in the process chamber 100 because of the interaction with the magnetic field. This plasma P dissociates the process gas and generates ion radicals. A process such as etching the wafer W is performed by controlling the antenna high frequency power source 123 and bias power source 134.

The powers supplied from the power sources are 100 W from the antenna power source 121, 300 W from the antenna high frequency power source 123, and about 800 W from the bias power source 141. After the etching process, supply of the power and process gas is stopped to terminate the etching process.

Optical information reflecting the plasm emission and the wafer surface state during the process is transmitted via the measuring ports 140 and the like by the optical transmission unit 151 and the like, and measured by the measuring instrument 152. In accordance with the measurement result, the measuring instrument control and calculation unit 153 performs calculations. The calculation result is transmitted to the upper level system controller 154 to control the plasma processing apparatus or system via the control interface 155.

More specifically, light of multi-wavelength is introduced from a measuring light source (e.g., a halogen lamp) of the measuring instrument 152 including a spectrometer for the calculation of an etch amount (e.g., an etch depth and a film thickness) into the vacuum chamber 103 by the optical transmission unit 151 and becomes incident upon the sample W generally vertically.

As shown in FIG. 2, in this embodiment, the sample W has a lamination structure of an organic photoresist film 44 as a mask, and a BARC (Back Anti-Reflection Coating: organic antireflection) film 43, a silicon nitride film 42 and a silicon oxide film 41 as films to be processed, respectively stacked upon a silicon substrate 40. As light is radiated in the vacuum chamber 103, radiation light 9A and 9B reflected from the surface of the films to be processed forms interference light, whereas radiation light 10A and 10B reflected from the top and bottom surfaces of the mask forms interference light. Namely, as radiation light 9 is introduced to the films to be etched without involving the mask 44, interference light is formed by radiation light 9A reflected from the upper surface of the BARC film 43 and radiation light 9B reflected from the interface between the silicon substrate 40 and silicon oxide film 41. As radiation light 10 is introduced to the mask 44, interference light is formed by radiation light 10A reflected from the top surface of the mask 44 and radiation light 10B reflected from the interface between the mask 44 and BARK film 43.

These interference beams are interference components caused by an etch of the mask 44 and an etch (an etch amount 50) of the film (BARC film). These interference beams are superposed and guided via the measurement port 140 and optical transmission unit 152 to the spectrometer of the measuring instrument 152. In accordance with an output signal from the spectroscope, the measuring instrument control and calculation unit 153 performs a process of determining the etch amount of a film to be processed, a thickness of a mask, and an end point of a process (etching process).

The measuring instrument 152 has the spectrometer, and the measuring instrument control and calculation unit 153 has a first digital filter circuit, a differentiator and a second digital filer which receive a data signal from the measuring instrument and performs a predetermined process. The measuring instrument control and calculation unit 153 also has; a storage unit for storing a database of differential waveform patterns to be used for determining an etching state such as a film thickness and an etching endpoint; a differential waveform comparator; a calculation unit for determining an etching endpoint from the comparison result; and the display unit 156 for displaying the data signal, processed data, and a determination result to a user.

The display unit 156 may be a liquid crystal display or a CRT display, a notice unit for notifying a completion of a predetermined film thickness and an endpoint with light, sound or the like, or a combination of these. In this embodiment, the display unit 156 has a display for displaying measured data as a graph and a notice unit for notifying a completion with light, sound or the like.

This embodiment functions, furthermore, to display particular information using or modifying said measured data displayed on the display unit 156, which are required by a user of this apparatus watching the display unit 156 and acknowledging the data displayed on, and/or to get the user point out data for determining or calculating said particular information.

For example, it has a pointing device for pointing particular or arbitrary points or data on these, and a calculating or determining device for calculating or determining a data value of the point on the coordinates and, using said data value, particular information which indicates the etching state such as the time between two points and wave length of points and the etching rate and the thickness of a film etc., information which are displayed at predetermined positions for easy acknowledgement.

As the calculating device for calculating said data values or information, the calculation unit disposed in the measuring instrument control and calculation unit 153 may be used, or another calculating device disposed far from this apparatus and able to transmit or receive signal including data measured or determined or calculated.

FIG. 1 shows a functional structure of the apparatus of measuring an etch amount. An actual structure of the display unit 156 and the measuring instrument 152 excepting the spectrometer includes: a CPU; a storage unit such as a ROM for storing a program of measuring an etch depth and a film thickness and various data including a differential waveform pattern database of interference light, a RAM for storing measured data and an external storage unit; a data input/output unit; and a communication control unit. This actual structure applies also to the other embodiments to be described later.

The outline of a process to be executed by the measuring instrument 152 and the measuring instrument control and calculation unit 153 in accordance with light emission in the vacuum chamber 103 will be described. The intensities of light emission of multi-wavelength measured with the measuring instrument 152 shown in FIG. 1 in connection with the film and mask are subjected to a smoothing process as time series data signals, and stored in the storage unit such as a RAM as smoothed differential coefficient time series data. An actual pattern (using a wavelength as a parameter) representative of a wavelength dependency of a differential value of the interference light intensity is obtained from the smoothed differential coefficient time series data.

A differential waveform pattern data value of an interference light intensity in the wavelength band corresponding to the steps of a film to be processed and a mask is preset in a differential waveform pattern database. The differential waveform pattern is displayed on the display unit 156 as an etch amount of a film to be etched.

If a broad area of a film to be etched is to be measured and controlled, a plurality of spectrometers may be used.

Furthermore, without the light source supplying the light inside the vacuum chamber 103 as shown in this embodiment above, the interference light of the plasma light in the chamber 103 can be measured by the measuring instrument 152 using the measuring port 140 and the optical transmission unit 151. In this case, the plasma light reflected on a surface of the wafer may be received by the measuring port 140. And, another measuring port 160, another optical transmission unit 161 are disposed on the sidewall so that the light inside the chamber 103 can be received and determined as a signal used as a reference, i.e. a reference light. The reference light is required not to be received directly from the wafer surface and to be the light by which a change of the plasma light is distinguishable. In this embodiment, the reference light is received by the receive unit disposed on the sidewall of the chamber 103.

FIG. 2 is a cross sectional view of films during an etching process. FIG. 3 shows an example of an actual wavelength pattern of interference light obtained during processing a wafer W. Referring to FIG. 2, a member (wafer) to be processed has a mask 41 stacked over the silicon substrate 40. In this etching process, the silicon substrate is a member to be etched. This process is called, for example, STI (Shallow Trench Isolation) etching for element separation.

In FIG. 3, the abscissa represents an etching time, and the ordinate represents a wavelength in a predetermined range. The intensity of light at each wavelength at each etching time is represented by shading. As shown in the graph of FIG. 3, depending upon the wavelength of interference light, a change pattern of intensity changes with an etching time. The differential waveform of interference light in the long wavelength region (second wavelength band: e.g., 700 nm) has a longer period of intensity change with an etching time and a relatively slow intensity change. A raw waveform of interference light in a short wavelength region (first wavelength band: e.g., 300 nm) has a shorter period than that of the long wavelength region.

As also seen from this graph, by processing a change in light emission in the vacuum chamber 103, a change in interference components by etching of the mask and a change in interference components by the film and mask can be made definite. This is because the refraction coefficients of materials to be etched change with a wavelength (e.g., refraction factors of silicon, nitride film as a mask, and vacuum in the groove region).

It is also seen from this graph that a change pattern of differential interference light is classified into three regions as the etching time lapses. Namely, as shown in FIG. 3, interference light is generated during etching the BARC film, silicon nitride (SiN) film and silicon oxide (SiO₂) film. In each region, an area with deep color indicating a large data value has a specific pattern on the coordinate plane (dimension) of wavelength and time. Namely, data having a value larger than a predetermined value and data having a value smaller than the predetermined value are alternately disposed in a stripe pattern on the coordinate plane. Namely, a “ridge” area having a large value and a “valley” area having a small value are alternately disposed. These “ridge” and “valley” represent a change with time of the wavelength of interference light having a value larger or smaller than a specific value. An area of the “ridge” in the strip pattern has a partial area in which the value is small, as if the “ridge” is cut.

According to the studies made by the present inventors, these patterns are formed because the interference light by etching of the film and mask is superposed. The pattern of the “ridge” and “valley” represents the intensity of interference light by etching of the film, and the area having a small value and cutting the “ridge” is formed because the interference light by etching of the mask is superposed upon the interference light by etching of the film.

The pattern of the “ridge” and “valley” is formed by interference of light emission (reflected light) from a wafer surface which changes with an etching time of the film. The pattern therefore reflects an etching progress and state and its change. By utilizing the characteristics of data patterns, the etch state (remaining film thickness and arrival of an endpoint) of a film can be determined so that the etch state of the mask can be determined. As shown in FIG. 3, when a semiconductor wafer having a lamination structure of films is to be processed, the above-described pattern characteristics appear in each film so that the etching progress with a time lapse can be made clear and a change in the etching state with time can be detected. The prevent invention is based upon these knowing and studies of the present inventors.

With reference to FIG. 4, an example of display data of interference light of the embodiment will be described. FIG. 4 shows an example of the etching state displayed on the display unit of the first embodiment by using the data shown in FIG. 3.

In the graph shown in FIG. 4, the differential data of interference light is shown with the abscissa representing an etching time and the ordinate representing the wavelength of interference light. By using the displayed data, the following points can be known. A time taken to etch each film can be known from the time length of each of a plurality of regions corresponding to respective materials of the films and divided in accordance with the data pattern change with time. If the thickness of each film is known accurately in advance, the etching rate can be known from this time.

In each region, it is possible to select a particular “ridge” and draw a line superposed upon the ridge and interconnecting specific coordinates (in this embodiment, (a, b), (c, d) and (e, f)). The “ridge” on this line indicates that how the etching of a corresponding material (BARC, SiN, SiO₂) proceeds with time. If the refraction factor and the like of film material are known, the etching rate of the material can be detected from the line on the “ridge”. By using the etching rate detected from the pattern of differential data of interference light, it is possible to highly precisely determine and judge the etching state such as a film thickness during etching and an etching endpoint. Since the etching time of each region corresponding to each material can be detected (since the etching time of each film can be detected), the film thickness of each material can be detected at a high precision. For such detection and judgement, the characteristics of a change in interference light to be caused by etching of material are utilized, the influence of superposition of interference light by etching of a mask and interference light by etching of a film can be suppressed greatly and the erroneous detection can be minimized.

The data indicating the etching state is displayed on the display unit 156 such as a graphic display unit in the form of numeral values or graphs. This data may be stored in the storage unit. A user can know a change with time of differential data of interference light, an etching state, a remaining film thickness, an etching rate and the like measured with the apparatus. Useful information necessary for a user to run the apparatus can be provided and the efficiency of running the apparatus can be improved.

The differential waveform pattern of interference light is specific to each state of film material. This pattern changes with film material. Therefore, data of various materials and etch depths is obtained beforehand by experiments or the like, and differential waveform patterns are desired to be stored in the storage unit as standard patterns. The storage unit may be provided in the measuring instrument control and calculation unit 153 or in an external storage unit connected via a cable.

Next, another embodiment of the invention will be described in which the etching state is determined at a higher precision by using the differential waveform pattern of interference light.

In the first embodiment, prior to processing a target wafer, a sample wafer is etched to obtain an etching rate and film thickness. These etching rate and film thickness are used as reference data when the target wafer is processed. This reference data is used on the assumption that the etching conditions of the sample wafer and target wafer are in a predetermined range of difference.

According to conventional techniques, a sample wafer is processed to obtain reference data each time the specification of etching conditions is changed. Therefore, for example, if each lot uses a different specification of etching gas, a sample wafer is processed to obtain reference data for each specification, which requires an additional work time. If a small number of wafers of a small lot are to be processed under different conditions, an efficiency of processes is lowered.

If a sample wafer processed show peculiar phenomenon, reference data influenced by such peculiar phenomenon is used. If a target wafer is processed in accordance with this reference data, the process itself is unpractical so that the processed semiconductor device cannot satisfy the predetermined specification and a manufacture yield may be lowered.

In this embodiment, reference data is obtained by using precess data under different etching conditions such as different etching gas specifications.

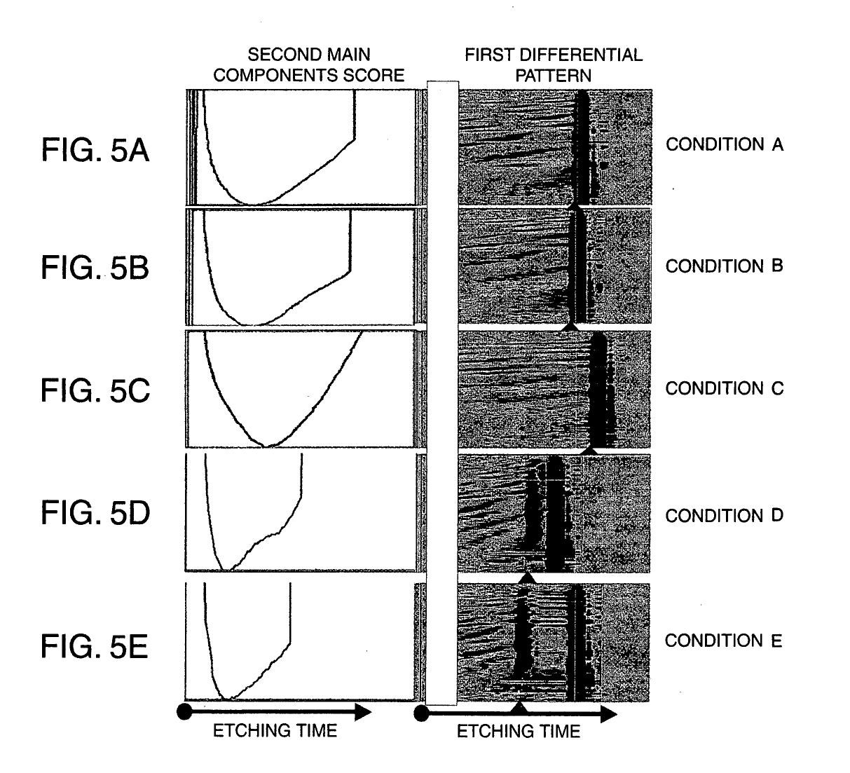

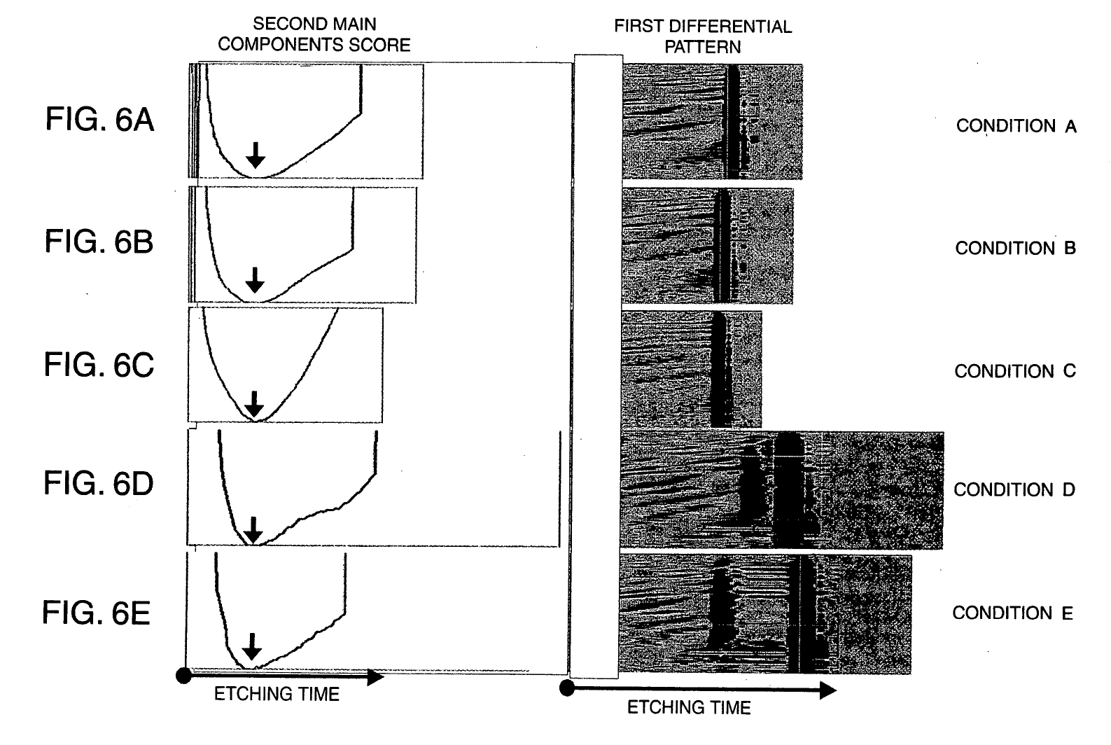

FIGS. 5A to 5E are graphs showing data of differential waveforms of interference light obtained during etching processes having different conditions. Since different etching conditions are used, the data of each differential waveform of interference light has a different pattern. A distribution of large and small values and a process time are different in each etching condition, which shows a different etching rate. FIGS. 6A to 6E are graphs showing patterns of differential waveforms of interference light under different etching conditions when the patterns are matched by using a specific parameter.

For the patterns shown in FIGS. 6A to 6E, specific components, the second main components in this embodiment, are used as the specific parameter, the second main components being obtained by analyzing main components of the data of differential waveforms shown in the right side area of FIGS. 6A to 6E. As shown in FIGS. 5A to 5E, the positions of peaks (minimum values) of the second main components obtained from the waveform data under different etching conditions are different. Data superposed can be either determined signal of the interference light or differentiated wave of it. A user of this apparatus can select and command to this apparatus. A quantity represented by the first main components of the waveforms of the interference light corresponds to the property of an average specific spectrum of interference light of multi-wavelength indicating plasma emission. A quantity represented by the second main components indicates a shift from the first main components and is a quantity representative of a shift of plasma emission interference light. The minimum value means a zero-cross point of a differential value of the second main components.

The studies made by the present inventors have found the following points. As shown in the graphs of FIGS. 6A to 6E, the differential patterns in the right column are generally analogous in a predetermined range when the etching time along the abscissa is expanded or contracted in such a manner that the peaks (minimum values) of waveforms of the second main components indicated by arrows in the left column take approximately the same position. A distribution of large and small value areas is generally analogous.

By using the data obtained under different etching conditions and having the matched patterns, the etching state can be determined at a high precision. For example, by using an average value obtained by superposing a plurality of data sets having generally analogous patterns, the etching state can be determined at a high precision by eliminating the influence of data pattern obtained under peculiar phenomenon or conditions.

When a plurality of data sets are superposed, the data sets are converted into values of a predetermined coordinate system of reference abscissa (time) and ordinate (wavelength). For example, if the patterns (positions of minimum values of the second main components) are to be matched by expanding the abscissa of the time axis more than the reference coordinate system, it is necessary to calculate data between coordinate points of the reference coordinate system. This data can be calculated by a known mathematical interpolation method.

Without converting data obtained in different etching conditions, as shown in FIG. 6, data obtained from a plurality of wafer processed in a same etching condition can be superposed or averaged. When film constructions of these wafers are almost same, it is not necessary to convert the data and superpose as shown in FIG. 6. In such an embodiment, influences caused by small deviations or fluctuations of the measured data value of interference light in the coordinates of time-wavelength changing according to time during processing wafers, such as noises etc., are reduced, which clears changes of values of interference light at each wave length. Especially, in larger wavelength reduced the small fluctuation, get cleared the changes of interference light. Thus, influences by the light from photo-resist film can be restrained, and etching states of a material film for the process can be determined more clearly.

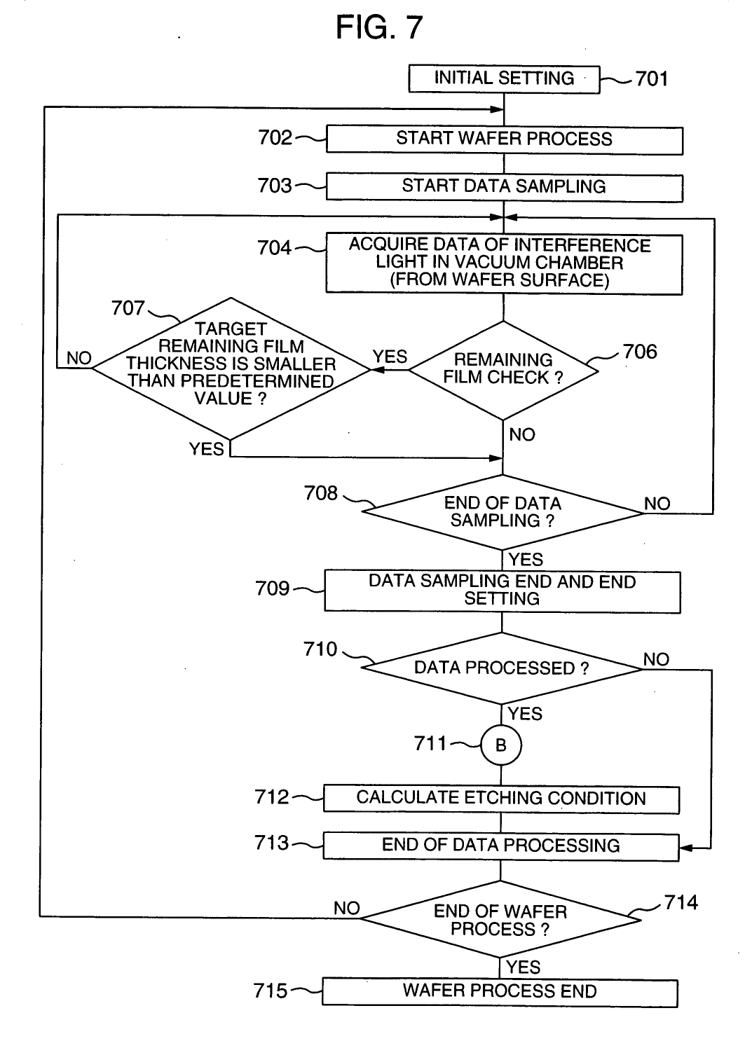

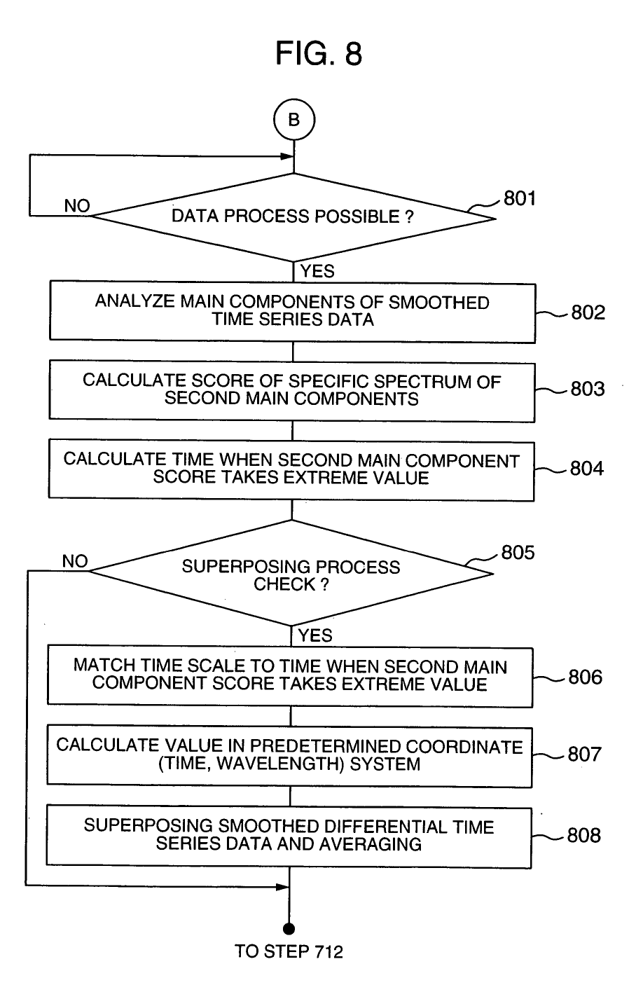

Next, the operation of determining the etching state to be executed by the semiconductor device fabricating apparatus of this embodiment will be described with reference to FIGS. 7 and 8. FIG. 7 is a flow chart illustrating a process of determining an etching state of the semiconductor device fabricating apparatus shown in FIG. 1. FIG. 8 is a flow chart illustrating a process at Step 711 B shown in FIG. 7.

The flow chart shown in FIG. 7 illustrates a wafer process (in this embodiment, wafer etch) in which a sample wafer is etched to collect data from which data a predetermined etching state such as an etching rate is obtained, and then an actual wafer process is performed.

The semiconductor device fabricating apparatus of the embodiment first performs initial setting before a wafer process, at Step 701 shown in FIG. 7. Initial setting is concerned about the name of a database for storing data of a sample wafer, an identifier of a wafer to be processed, Step number of determining a remaining film thickness, a target remaining film thickness, a reference value to be used for an endpoint determination and the like. After Step 701, a wafer process starts at Step 702.

At Step 703 when it is confirmed that the wafer process starts, data is sampled during the wafer process. At Step 704 light emission in the vacuum chamber 100 including light reflected from the wafer surface is received by the spectrometer of the measuring instrument 152 via the measurement port 140 and optical transmission unit 151 to acquire data of interference light under the control of the measuring instrument control and calculation unit 153.

More specifically, this data acquired at Step 704 is output as time series signals of light of multi-wavelength in the vacuum chamber 100 transmitted from the optical transmission unit 152 to the spectrometer, and subjected to a smoothing process by a digital filter or the like in the measuring instrument control and calculation unit 153. Differential coefficients of the smoothed data are calculated by a known method (such as S-G method) and again smoothed by the digital filter. The differential data of waveforms of interference light of multi-wavelength is used as the data of a time-wavelength coordinate system. This data is compared with a reference data to calculate a remaining thickness of a film on the wafer.

Next, at Step 706 it is checked whether a remaining film thickness is to be checked. If not, the flow advances to Step 708 whereat it is judged whether the current wafer data sampling is terminated. If it is judged at Step 706 that the remaining film thickness check is to be performed, then at Step 707 it is judged whether the remaining thickness of the film is smaller than a predetermined value corresponding to the judgement criterion. If larger than the predetermined value, the flow returns to Step 704 to continue the wafer process and data sampling. If it is judged that the remaining film thickness is smaller than the predetermined value, the flow advances to Step 708. If it is judged at Step 708 that the data sampling is to be terminated, the data sampling is terminated and necessary end setting is performed.

It is judged next at Step 710 whether the acquired data is processed. If it is judged that data processing is not necessary, the slow skips from Step 710 to Step 713 and to Step 714 whereat it is judged whether the wafer process is terminated. In this case, the acquired data may be stored in the storage unit such as a hard disk to use it later.

If it is judged at Step 711 that the acquired data is to be processed, the data is processed at Step 711 indicated by B. This process will be later detailed with reference to FIG. 8. By using the data processed at Step 711 B, the etching condition is calculated at Step 712. After the calculated etching condition is stored and recorded, the data processing is terminated to thereafter judge whether the wafer process is to be terminated at Steps 713 and 714. If it is judged that the wafer process is to be terminated, a predetermined wafer process termination operation is performed at Step 715. If it is judged that the wafer process is not terminated but a target wafer is etched after the sample wafer process, then the flow returns to Step 702.

The process at B shown in FIG. 7 will be detailed with reference to FIG. 8. At Step 801 it is checked whether the data process is possible. For example, a period is selected which excludes a period during which light in the vacuum chamber changes transiently because of a discharge start time, a charge eliminating sequence or the like. During the selected period capable of the data process, main components of the smoothed time series data are analyzed at Step 802.

At Step 803 a score of the second main components obtained by analyzing the main components is calculated. At Step 804 a time when the second main components take a minimum value (extreme value) of the second main components is calculated by a differential process or the like of the score relative to time. This differential process is performed by a known method such as an S-G method.

It is judged at Step 805 whether a superposing process of time-wavelength differential waveform data obtained during the wafer process under a different etching condition is to be performed relative to the time when the second main components take the extreme value. If to be performed, at Step 806 in order to match the superposed patterns, the time scale is changed in such a manner that the extreme values of the second main components have the same time.

Next, at Step 807 a value in the predetermined coordinate system (time-wavelength) is calculated for superposition by using a known interpolation method. At Step 808 by using the calculated value, a superposing and averaging process is performed. By using the data obtained in this manner, data of the etching state such as an etching rate and time is calculated so that data of the etching state can be obtained at a high precision without the influence of data under a peculiar phenomenon during the data sampling.

Each pattern of data in a specific region (time-wavelength) obtained under a plurality of etching conditions can be used although conventional techniques are impossible. Accordingly, a wafer process efficiency can be improved and the data used for judgement during an actual wafer process is highly precise. Even if a specification of wafer material, etching gas and the like is changed frequently, a semiconductor device can be processed at a higher efficiency and yield.

In such an embodiment above, data storing or maintaining unit like a harddisk, such data obtained during processing a wafer, for recording or reminding data may be disposed in the apparatus as a part of it or outside connected by a cable or wireless able to transmit and/or receive data signals with the measuring instrument control and calculation unit 153. And data signals necessary can be transmitted between the apparatus and the data—storing unit disposed far apart from the apparatus connected there between by network. Furthermore, by using transmitted data from such data storing unit, data which obtained by another apparatus processing another wafer, etching state can be determined more correctly, although in fewer cycles of processes, and a wafer or a semiconductor device can be processed at a higher efficiency and yield.

Also, the user of this apparatus can select data from a plurality of data maintained on the storing unit, and command to superpose these data with each other or with the data obtained by this apparatus, calculate data value and display on the display unit 156. Furthermore, the user of this apparatus may select a storing unit for storing and maintaining data obtained on this apparatus from a plurality of storing units.

It should be further understood by those skilled in the art that although the foregoing description has been made on embodiments of the invention, the invention is not limited thereto and various changes and modifications may be made without departing from the spirit of the invention and the scope of the appended claims.

What is claimed is:

1. A semiconductor device fabricating method for etching a sample to be processed, which is placed within a vacuum chamber and has a plurality of films formed on a surface thereof, by using plasma generated within the vacuum chamber, comprising the steps of:
a) detecting interference lights of multiple wavelengths emitted from a surface of one sample to be processed during a processing of the sample to be processed;
b) obtaining an intensity of the interference lights of multiple wavelengths from the detected interference lights of multiple wavelengths emitted from the surface of the one sample thereby to obtain one pattern consisting of time differential values of the detected interference lights of multiple wavelengths with respect to the one sample using a time as a parameter;
c) prior to steps a) and b), detecting interference lights of multiple wavelengths emitted from a surface of another sample to be processed to obtain an intensity of the interference lights of multiple wavelengths, and to obtain another pattern consisting of time differential values of the detected interference lights of multiple wavelengths with respect to the another sample using a time as a parameter;
d) superposing data constituting the one pattern and data constituting the another pattern after that the one pattern and the another pattern are matched by using a specific parameter, thereby obtaining a superimposed pattern; and
e) detecting a state of an etching process of the one sample based on the superimposed pattern.

2. A semiconductor device fabricating method according to claim 1, wherein the specific parameter is a time point where second components obtained by analyzing main components of the data constituting the one and another patterns becomes peak.

3. A semiconductor device fabricating method according to claim 2, wherein the one sample and the anther sample are etched under different conditions, respectively.

4. A semiconductor device fabricating method according to claim 2, further comprising the steps of:
detecting a speed of the etching process based on the superimposed pattern.

5. A semiconductor device fabricating method according to claim 3, wherein the step e) includes substeps of:
detecting a speed of the etching process based on the superimposed pattern; and
detecting the state of the etching process of the one sample based on the speed of the etching process thus detected.

6. A semiconductor device fabricating method according to claim 1, wherein the one sample and the anther sample are etched under different conditions, respectively.

7. A semiconductor device fabricating method according to claim 6, wherein the step e) includes substeps of:
detecting a speed of the etching process based on the superimposed pattern; and
detecting the state of the etching process of the one sample based on the speed of the etching process thus detected.

8. A semiconductor device fabricating method according to claim 1, wherein the step e) includes substeps of:
detecting a speed of the etching process based on the superimposed pattern; and
detecting the state of the etching process of the one sample based on the speed of the etching process thus detected.

9. A semiconductor device fabricating method for etching a sample to be processed, which is placed within a vacuum chamber and has a plurality of films formed on a surface thereof, by using plasma generated within the vacuum chamber, comprising the steps of:
a) detecting interference lights of multiple wavelengths emitted from a surface of one sample to be processed during a processing of the sample to be processed;
b) obtaining an intensity of the interference lights of multiple wavelengths from the detected interference lights of multiple wavelengths emitted from the surface of the one sample thereby to obtain one pattern consisting of time differential values of the detected interference lights of multiple wavelengths with respect to the one sample using a time as a parameter;
c) prior to steps a) and b), detecting interference lights of multiple wavelengths emitted from a surface of another sample to be processed to obtain an intensity of the interference lights of multiple wavelengths, and to obtain another pattern consisting of time differential values of the detected interference lights of multiple wavelengths with respect to the another sample using a time as a parameter;
d) superposing data constituting the one pattern and data constituting the another pattern after that the one pattern and the another pattern are matched by using a specific parameter, and averaging the data thus superimposed thereby to obtain a superimposed pattern; and
e) detecting a state of an etching process of the one sample based on the superimposed pattern.

10. A semiconductor device fabricating method according to claim 9, wherein the specific parameter is a time point where second components obtained by analyzing main components of the data constituting the one and another patterns becomes peak.

11. A semiconductor device fabricating method according to claim 10, wherein the one sample and the anther sample are etched under different conditions, respectively.

12. A semiconductor device fabricating method according to claim 11, further comprising the steps of:
detecting a speed of the etching process based on the superimposed pattern.

13. A semiconductor device fabricating method according to claim 10, wherein the step e) includes substeps of:
detecting a speed of the etching process based on the superimposed pattern; and
detecting the state of the etching process of the one sample based on the speed of the etching process thus detected.

14. A semiconductor device fabricating method according to claim 9, wherein the one sample and the anther sample are etched under different conditions, respectively.

15. A semiconductor device fabricating method according to claim 14, wherein the step e) includes substeps of:
detecting a speed of the etching process based on the superimposed pattern; and
detecting the state of the etching process of the one sample based on the speed of the etching process thus detected.

16. A semiconductor device fabricating method according to claim 9, wherein the step e) includes substeps of:
detecting a speed of the etching process based on the superimposed pattern; and
detecting the state of the etching process of the one sample based on the speed of the etching process thus detected.
